(19) United States
(12) Patent Application Publication
(10) Pub. No.: US 2025/0311137 A1
(43) Pub. Date: Oct. 2, 2025

(54) LEAKAGE PROTECTION DEVICE WITH LOAD-END FUNCTIONS

(71) Applicant: Chengli LI, Suzhou (CN)

(72) Inventors: Chengli LI, Suzhou (CN); Xiaoming ZHANG, Suzhou (CN); Long CHEN, Suzhou (CN); Jinxin ZHANG, Suzhou (CN)

(73) Assignee: Chengli LI, Suzhou (CN)

(21) Appl. No.: 19/236,784

(22) Filed: Jun. 12, 2025

Related U.S. Application Data
(63) Continuation of application No. PCT/CN2025/098351, filed on May 30, 2025.
(63) Continuation-in-part of application No. 19/098,807, filed on Apr. 2, 2025.
Application No. 19/098,807 is a continuation-in-part of application No. 18/350,817, filed on Jul. 12, 2023.

(30) Foreign Application Priority Data
Jun. 16, 2023 (CN) 202310715960.5
Jun. 16, 2023 (CN) 202321540120.1
Mar. 28, 2025 (CN) 202520561875.2
May 30, 2025 (CN) 202510719291.8
May 30, 2025 (CN) 202521107491.X

(51) Int. Cl. H05K 7/14; G01R 31/52; H05K 5/02; H05K 7/20

(52) U.S. Cl. CPC H05K 7/1427; G01R 31/52; H05K 5/0217; H05K 7/2039

(57) ABSTRACT

A leakage protection device includes a housing, an input terminal extending from a lower surface of the housing for coupling to a power supply, an output terminal for coupling a load, and a core assembly disposed in the housing. The core assembly includes: a first printed circuit board (PCB) and a second PCB, stacked parallel to each other, where the component surfaces of the first and second PCBs are parallel to the lower surface of the housing; a leakage protection assembly, including a trip coil assembly and a detection magnetic ring to detect a leakage current signal at the output terminal; an additional functional assembly, coupled to the leakage protection assembly and including the first or second PCB to perform at least one load end function, and a heat dissipation assembly disposed between the first and/or second PCB and the housing and/or between the first and second PCBs.

### BACKGROUND OF THE INVENTION

The present invention generally relates to the field of leakage protection devices, and more particularly to a leakage protection device with additional (e.g., load-end) functions.

With the improvement of living standards and people's awareness of electricity safety, the application scenarios of devices with leakage protection function are becoming more and more extensive. Traditional leakage protection devices only provide leakage protection functions, but with the changes in market demand, the types of electrical equipment or loads that are equipped with leakage protection devices are also increasing. With the increasing reliability and functional requirements of leakage protection devices, the new functions of certain loads have put forward additional functional requirements for leakage protection devices, as well as additional safety requirements, especially electrical devices used in personal care. Therefore, there is a need for a device that can add some functions of load-side electrical equipment to leakage protection devices.

### SUMMARY OF THE INVENTION

Accordingly, embodiments of the present invention provide a leakage protection device with additional functions, which meets the market demand for additional functions and safety requirements at the load end with an optimal structural layout and a compact appearance design.

According to embodiments of the present disclosure, a leakage protection device with additional functions includes a housing, an input terminal for coupling to a power supply, an output terminal for coupling to an electrical load, and a core assembly disposed in the housing, wherein the input terminal is attached to the lower surface of the housing, and the core assembly at least includes: a first printed circuit board and a second printed circuit board, wherein the first printed circuit board and the second printed circuit board are stacked parallel to each other, and component surfaces of the first printed circuit board and the second printed circuit board are parallel to the lower surface of the housing; a leakage protection assembly, including at least a trip coil assembly and a detection magnetic ring to detect a leakage current signal at the output terminal; an additional functional assembly, wherein the additional functional assembly is coupled to the leakage protection assembly and includes at least one of the first printed circuit board and the second printed circuit board to perform at least one load end function; and a heat dissipation assembly disposed between the first printed circuit board and/or the second printed circuit board and the housing and/or between the first printed circuit board and the second printed circuit board.

Based on the above technical characteristics, the present invention may include any one or more of the embodiments below.

In some embodiments, the heat dissipation assembly is disposed adjacent to the heat generating elements on the first printed circuit board and/or the second printed circuit board, and is used to dissipate heat for the heat generating elements.

In some embodiments, the heat generating elements on the first printed circuit board and the heat generating elements on the second printed circuit board are disposed to face opposite directions and toward the inner surface of the housing.

In some embodiments, the heat dissipation assembly includes at least one heat dissipation element, which has a base wall parallel to the first printed circuit board or the second printed circuit board, and at least a pair of side walls extending vertically from the edge of the base wall and parallel to each other, wherein the base wall is disposed at least between the first printed circuit board or the second printed circuit board and the inner surface of the housing, and the at least one pair of side walls cover at least a portion of the core assembly.

In some embodiments, the heat dissipation element further includes at least one pair of side surrounding walls, which extend at an angle from the edges of the at least one pair of side walls or extend vertically from the edge of the base wall and are connected to or spaced apart from the at least one pair of side walls, and the at least one pair of side surrounding walls extend toward each other to cover at least a portion of the core assembly.

In some embodiments, the at least one pair of side surrounding walls are adjacent to each other or spaced apart from each other.

In some embodiments, the heat dissipation assembly further includes at least one heat conductor, which is disposed corresponding to the position of the heat generating elements on the first printed circuit board and/or the second printed circuit board, and is respectively in contact with the heat generating elements and the at least one heat dissipation element to form a heat conduction path.

In some embodiments, the leakage protection device further comprises at least one insulator, and the at least one insulator is disposed between the at least one heat dissipation element and non-heat generating elements of the first printed circuit board and/or the second printed circuit board for isolation and insulation.

In some embodiments, the contour shapes of the at least one insulator and the at least one heat dissipation element are configured to at least partially match each other.

In some embodiments, the at least one insulator has an opening, and the at least one heat conductor is in contact with the at least one heat dissipating element via the opening.

In some embodiments, the shapes of the opening and the heat conductor match each other.

In some embodiments, the heat dissipation assembly includes a first base wall parallel to the first printed circuit board or the second printed circuit board, and at least a pair of side walls extending vertically from the edge of the first base wall and parallel to each other, wherein the first base wall is disposed between the first printed circuit board and the inner surface of the housing, the heat dissipation assembly further includes a second base wall parallel to the first base wall, wherein the second base wall is disposed between the second printed circuit board and the inner surface of the housing, and wherein the at least one pair of side walls cover at least a portion of the additional functional assembly.

In some embodiments, the heat dissipation assembly includes at least a first heat dissipation element and a second heat dissipation element, wherein the first heat dissipation element includes at least the first base wall, and the second heat dissipation element includes at least the second base wall.

In some embodiments, the first heat dissipation element includes at least one pair of first side walls extending vertically from the edge of the first base wall and parallel to each other, and the second heat dissipation element includes at least one pair of second side walls extending vertically from the edge of the second base wall and parallel to each other.

In some embodiments, the first heat dissipation element and the second heat dissipation element are connected to each other and cover at least a portion of the core assembly.

In some embodiments, the first heat dissipation element and the second heat dissipation element are fixedly connected by a snap-fit structure provided on the at least one pair of first side walls and the at least one pair of second side walls.

In some embodiments, the at least one pair of first side walls of the first heat dissipation member and the at least one pair of second side walls of the second heat dissipation member partially overlap.

In some embodiments, the first heat dissipation element further includes at least one pair of first side surrounding walls, which extend at an angle from the edges of the at least one pair of first side walls or extend vertically from the edge of the first base wall and are connected to or spaced apart from the at least one pair of first side walls, and the at least one pair of first side surrounding walls extend toward each other to cover at least a portion of the additional functional assembly, and/or the second heat dissipation element further includes at least one pair of second side surrounding walls, which extend at an angle from the edges of the at least one pair of second side walls or extend vertically from the edge of the second base wall and are connected to or spaced apart from the at least one pair of second side walls, and the at least one pair of second side surrounding walls extend toward each other to cover at least a portion of the leakage protection assembly.

In some embodiments, the at least one pair of first side surrounding walls are adjacent to or spaced apart from each other, and/or the at least one pair of second side surrounding walls are adjacent to or spaced apart from each other.

In some embodiments, the leakage protection device includes a first insulator disposed between the first heat dissipation element and the non-heat generating elements of the first printed circuit board, and a second insulator disposed between the second heat dissipation element and the non-heat generating elements of the second printed circuit board.

In some embodiments, the contour shapes of the first insulator and the first heat dissipation element are configured to at least partially match each other, and/or the contour shapes of the second insulator and the second heat dissipation element are configured to at least partially match each other.

In some embodiments, the leakage protection device further includes a middle bracket, which is disposed between the leakage protection assembly and the additional functional assembly, wherein the heat dissipation assembly is affixed to the middle bracket.

In some embodiments, the heat dissipation assembly and the middle bracket are fixedly connected by a snap-fit structure and/or fasteners.

In some embodiments, the heat dissipation assembly includes a middle-layer heat dissipation element, which is disposed in the middle bracket and adjacent to the heat generating elements of the first printed circuit board and/or the second printed circuit board.

In some embodiments, the middle-layer heat dissipation element has a middle-layer base wall parallel to the first printed circuit board or the second printed circuit board, and at least a pair of middle-layer side walls extending vertically from the edge of the middle-layer base wall and parallel to each other, wherein the middle-layer base wall is disposed between the first printed circuit board or the second printed circuit board and the middle bracket, and the at least a pair of middle-layer side walls cover at least a portion of the heat generating elements of the first printed circuit board and/or the second printed circuit board.

In some embodiments, the middle-layer heat dissipation element also includes at least one pair of middle-layer side surrounding walls, which extend at an angle from the edges of the at least one pair of middle-layer side walls or extend vertically from the edges of the middle-layer base wall and are connected to or spaced apart from the at least one pair of middle-layer side walls, wherein the at least one pair of middle-layer side surrounding walls extend toward each other to cover at least a portion of the heat generating elements of the first printed circuit board or the second printed circuit board.

In some embodiments, the at least one pair of middle-layer side surrounding walls are adjacent to each other or spaced apart.

In some embodiments, the leakage protection device further includes a heat conductor disposed between the middle-layer heat dissipation element and the heat generating elements of the first printed circuit board and/or the second printed circuit board, wherein the heat conductor is in contact with both the heat generating elements and the middle-layer heat dissipation element to form a heat conduction path.

In some embodiments, the middle bracket further includes a wire management block for bending the output power cord.

In some embodiments, the middle bracket further includes a wire baffle, and the wire management block is formed on the wire baffle.

In some embodiments, the heat dissipation assembly is formed integrally from a plate-like member by stamping.

In some embodiments, the leakage protection device includes at least four independent current-carrying wires, and the leakage protection assembly detects leakage current signals on the current-carrying wires.

In some embodiments, the first printed circuit board and the second printed circuit board are electrically connected by current-carrying wires or a conductive column.

In some embodiments, the input terminal includes at least two prongs extending out of the housing, wherein the first printed circuit board and the second printed circuit board are disposed perpendicular to the plugging direction of the prongs, wherein the prongs are coupled to the first printed circuit board or the second printed circuit board by current-carrying wires.

In some embodiments, the housing at least includes an upper housing and a lower housing, wherein the upper housing has an output terminal through hole for accommodating an output power cord, and wherein the prongs are fixed to the lower housing.

In some embodiments, the first printed circuit board is located farther away from the input terminal compared to the second printed circuit board, and the heat dissipation assembly is at least partially disposed between the first printed circuit board and the inner surface of the upper housing; or the first printed circuit board is located closer to the input terminal compared to the second printed circuit board, and the heat dissipation assembly is at least partially disposed between the first printed circuit board and the inner surface of the lower housing.

In some embodiments, the lower housing is fixedly connected to the upper housing by fasteners.

In some embodiments, the housing further includes a lower housing cover plate, which is fixedly connected to the lower housing and covers the lower housing, and the lower housing cover plate has through holes for the prongs to extend out.

In some embodiments, the lower housing cover plate is fixedly connected to the lower housing by a snap-fit structure and/or fasteners and/or adhesives.

In some embodiments, the lower housing cover plate is fixedly connected to the lower housing by an adhesive sheet, wherein the adhesive sheet includes through holes for the prongs to extend out and snap slots, and the lower housing cover plate has corresponding snap hooks.

In some embodiments, the leakage protection device further includes a wire crimping assembly configured to fix the output power cord in the housing, and configured to move only along the plugging direction of the prongs.

In some embodiments, the leakage protection device further includes a power cord bending buffer device, which includes a snap-fitting convex edge, and the convex edge passes through the output terminal through hole of the housing and fixedly engage with the wire crimping assembly.

In some embodiments, the wire pressing assembly includes a first wire pressing block and a second wire pressing block disposed opposite to each other along the plugging direction of the prongs, wherein the first wire pressing block includes first notches, the second wire pressing block includes second notches, the first notches and/or the second notches having inclined surfaces, and the inclined surfaces are engaged with the snap-fitting convex edge of the power cord bending buffer device.

In some embodiments, the load-end functions at least include a power conversion function and/or an electromagnetic compatibility filtering function and/or a switch control function.

In some embodiments, the first printed circuit board includes at least a rectifier circuit for converting the AC power connected to the input terminal into a DC power.

In some embodiments, the least two of the current-carrying wires are coupled to the rectifier circuit.

In some embodiments, the rectifier circuit at least includes a diode or a rectifier bridge.

In some embodiments, the device further includes a heat conductor disposed on the surface of the rectifier circuit.

In some embodiments, the leakage protection assembly at least includes a detection assembly and a disconnection assembly, wherein the detection assembly detects a leakage current signal at the output terminal, and the disconnection assembly disconnects an electrical connection between the input terminal and the output terminal in response to the leakage current signal.

In some embodiments, the detection assembly includes a detection magnetic ring, which has an inner hole and is coupled to the first printed circuit board or the second printed circuit board, and is configured to detect the leakage current signal of the current-carrying wires passing through the inner hole and transmit it to the first printed circuit board or the second printed circuit board.

In some embodiments, the disconnection assembly includes an input stationary contact assembly coupled to the input terminal and an output moving contact assembly passing through the inner hole of the detection magnetic ring and coupled to the output terminal, wherein the disconnection assembly disconnects the electrical connection between the input stationary contact assembly and the output moving contact assembly in response to the leakage current signal.

In some embodiments, the leakage protection assembly includes an operating member mechanically linked with the disconnection assembly, wherein the operating member includes a reset member and a tripping member to switch the input stationary contact assembly and the output moving contact assembly between a closed state and an open state.

In some embodiments, the operating member further includes a test member, coupled to the first printed circuit board or the second printed circuit board and configured to generate a simulated leakage signal.

In some embodiments, the leakage protection device further includes a status indicator, formed of a light-transmitting material and disposed between the first printed circuit board or the second printed circuit board and the housing.

Embodiments of the present invention integrate the additional functional assembly and the heat dissipation assembly in the leakage protection device, and can achieve at least part of the functions of the load-end electrical equipment in a limited space while providing the leakage protection function. Further, it provides heat dissipation of heat generating elements of the circuits, avoiding excessive local temperature on the housing surface, thereby ensuring the reliability of the leakage protection device while providing more diversified functions. The device is suitable for a variety of electrical equipment, and provides users with a richer leakage protection product integration solution. In addition, the leakage protection device has a simple structure and is easy to implement, providing wide applications of the device.

### BRIEF DESCRIPTION OF DRAWINGS

Other features and advantages of the present invention may be understood from the embodiments described below with reference to the drawings.

FIG. 1 is an exterior view of a leakage protection device according to an embodiment of the present invention.

FIG. 2 is an exploded view of the leakage protection device of FIG. 1.

FIG. 3 is an exploded view of the core assembly, the heat dissipation assembly, the heat conductor and the insulator in FIG. 2.

FIG. 4 is an exploded view from another angle of the core assembly, the heat dissipation assembly, the heat conductor and the insulator in FIG. 2.

FIG. 5 is an exploded view of the core assembly of FIG. 3.

FIG. 6 is an exploded view of the leakage protection assembly of FIG. 5.

FIG. 7A is a cross-sectional view showing the positions of various components of the leakage protection assembly when the assembly is in a disconnected state.

FIG. 7B is a cross-sectional view showing the positions of various components of the leakage protection assembly when the reset button is operated (pressed) in the state shown in FIG. 7A.

FIG. 7C is a cross-sectional view showing the positions of various components of the leakage protection assembly when the reset button is operated (released) in the state shown in FIG. 7B to put the leakage protection assembly in a closed state.

FIG. 8 is an exploded view of a leakage protection device according to another embodiment of the present invention.

FIG. 9 illustrates the assembled core assembly that includes a leakage protection assembly and an additional functional assembly in the leakage protection device of FIG. 8.

FIG. 10 is an exploded view of the core assembly of FIG. 9.

FIG. 11 illustrates the assembly of the core assembly, the housing and the button assembly in FIG. 8;

FIG. 12 illustrates the assembly of the core assembly, the upper cover of the housing, the output power cord assembly, and the wire crimping assembly.

FIG. 13A is a cross-sectional view of the leakage protection device in an assembled state in which the wire crimping assembly clamps and fixes the output power cord assembly to the through hole of the output side of the housing.

FIG. 13B illustrates the assembled leakage protection device where the power cord is bent into a U shape inside the housing by the wire management block and the wire baffle.

FIG. 14 is an exterior view of a leakage protection device according to another embodiment of the present invention.

FIG. 15 is an exploded view of the leakage protection device of FIG. 14.

FIG. 16 is an exploded view of the core assembly, the heat dissipation assembly, the heat conductor and the insulator in FIG. 15.

FIG. 17 is an exploded view of the core assembly of FIG. 16.

FIG. 18 is a circuit diagram of a leakage protection device according to an embodiment of the present invention.

### DETAILED DESCRIPTION OF THE INVENTION

The implementation and use of the embodiments are discussed in detail below. However, it should be understood that the specific embodiments discussed are merely exemplary of specific ways to implement and use the present invention, and are not intended to limit the scope of the present invention. When describing the structural positions of the various components, such as up, down, top, bottom, etc., the expressions of directions are not absolute, but relative. When the various components are disposed as shown in the figure, these directional expressions are appropriate, but when the positions of the various components in the figure change, these directional expressions also change accordingly.

In the descriptions below, terms such as “comprising”, “including”, “containing”, “having”, etc. are intended to be open-ended and do not exclude elements or components not specifically listed.

In this disclosure, unless otherwise indicated, terms such as “mount”, “connect”, “couple”, “link” etc. should be understood broadly; for example, they may be fixed connections, or removable or detachable connections, or integrally connected for integrally formed; they may be directly connected, or indirectly connected via intermediate parts, and may refer to internal connection of two components or mutual interactions of two components. Those skilled in the relevant art can readily understand the meaning of these terms as used in this disclosure based on the specific description and context.

In this disclosure, unless specifically indicated, terms such as “first”, “second”, etc. do not connote a temporal or spatial sequence or a particular number of parts.

Traditional leakage protection devices (e.g., leakage protection plugs) only have leakage shut off protection functions, and are relatively simple and have limited application scenarios. In order to meet more diversified application needs, for example, when the device is adapted to high-speed hair dryers, curling irons and other scenarios, it is necessary to solve high-frequency electromagnetic interference or provide DC power supply, and in order to make the load end light and compact, it is desirable to provide an electromagnetic compatibility module or a DC power supply module in the leakage protection plug, so as to provide users with a safe and comfortable experience.

Accordingly, in response to the trend that existing leakage protection devices need to be adapted to different electrical equipment and have increasing functional requirements, embodiments of the present invention provide a leakage protection device with additional functions, which realizes certain functions of electrical equipment and has an efficient structural layout and a compact design.

The leakage protection device in the form of a plug is described below as an example, but it should be understood that the leakage protection device may be applicable to other forms.

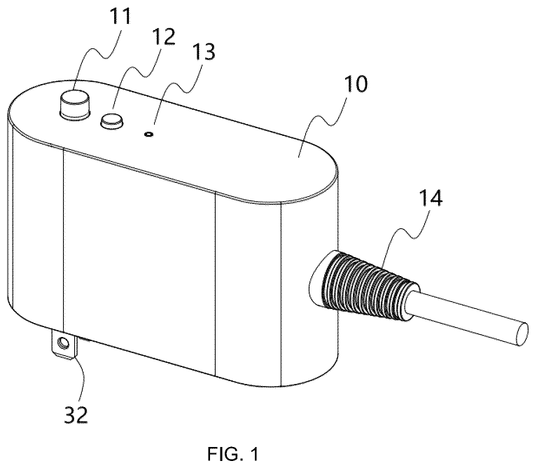

Referring to FIGS. 1 to 7C, a leakage protection device according to an embodiment of the present invention includes a housing and a core assembly disposed in the housing, as well as an input terminal and an output terminal (e.g., an output power cord assembly) fixedly connected to the housing and extending outside the housing. The housing may, for example, include an upper housing assembly 1 and a lower housing assembly 3 for supporting or fixing the various components in the housing. The upper housing assembly 1 may include an upper housing 10, a button assembly (e.g., a reset button 11, a test button 12, a status indicator 13, etc.), and the side of the upper housing 10 is also provided with an output terminal through hole for accommodating and passing a power cord, i.e., an output power cord assembly 14, to achieve electrical connection with an electrical load. The lower housing assembly 3 may include a lower housing 30. It should be understood that the terms “upper” and “lower” here refer to the orientation of the leakage protection device in the form of a plug shown in the figure when it is conventionally used, and are not intended to be limiting.

In the illustrated embodiment, the input terminal of the leakage protection device is used to couple a power supply, and the output terminal is used to couple an electrical load, wherein the input terminal is attached to the lower surface of the housing and includes at least two prongs 32 extending out of the housing and fixed to the lower housing 30, which are used to be inserted into a socket to obtain power. In some embodiments, the upper housing 10 and the lower housing 30 are assembled and fixed together using fasteners such as screws, and the lower housing assembly 3 may also include a lower housing cover plate 34 disposed on the outer side of the lower housing 30 to cover the screw holes. According to different needs, the lower housing cover plate 34 may be assembled and fixed to the lower housing 30 by a snap-fit structure and/or fasteners and/or adhesives, and cover the lower housing 30, and the lower housing cover plate 34 is correspondingly provided with through holes 342 for the prongs 32 to extend through the housing. In some embodiments, the lower housing cover plate 34 and the lower housing 30 may be fixedly connected by an adhesive sheet 33 (such as double-sided adhesive tape). The adhesive sheet 33 is provided with through holes 332 for the prongs 32 to extend out, and snap slots 331. The lower housing cover plate 34 is provided with corresponding snap hooks 341 to pass through the snap slots 331 and snap to the lower housing 30, thereby further achieving a stable connection.

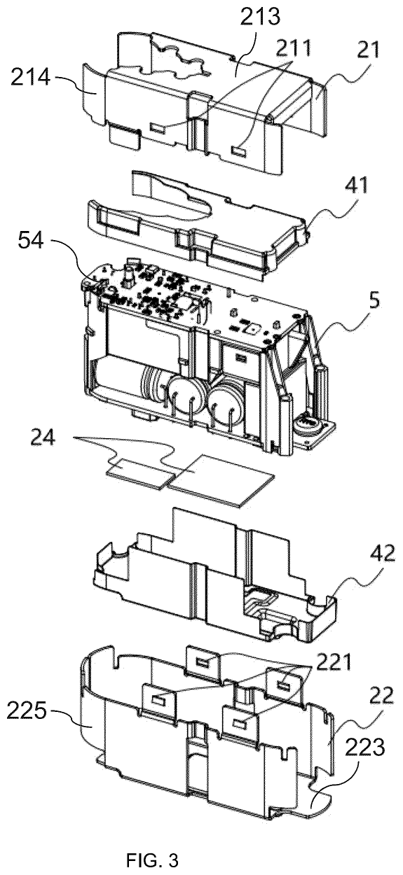

Referring to FIGS. 3-5, the core assembly 5 at least includes a first printed circuit board (PCB) 520 and a second printed circuit board 510, a leakage protection assembly 51 and an additional functional assembly 52, where the first printed circuit board and the second printed circuit board are stacked parallel to each other, and the component surfaces of the first printed circuit board and the second printed circuit board are parallel to the lower surface of the housing. The leakage protection assembly 51 at least includes a trip coil assembly and a detection magnetic ring to detect the leakage current signal at the output terminal. The additional functional assembly 52 is coupled to the leakage protection assembly 51 and includes at least one of the first printed circuit board and the second printed circuit board, for example, the first printed circuit board 520 shown in the figure as well as functional elements coupled to the first printed circuit board 520 to realize at least one load end function. Specifically, in some embodiments, the leakage protection device may include at least four independent current-carrying wires, and the leakage protection assembly 51 is used to detect the leakage current signal on the current-carrying wire.

According to the present embodiment, the load-end functions that may be realized by the additional functional assembly include at least a power conversion function (AC/DC or DC/DC conversion) and/or an electromagnetic compatibility (EMC) filtering function and/or a switch control function. The additional functional assembly 52 may combine or select any one or two, or all three of the above additional functions or other additional functions. It should be understood that the functional parts are various electric devices for realizing the above additional functions, including but not limited to capacitors, inductors, resistors, other impedance devices, etc. Accordingly, the first printed circuit board 520 has heat generating elements 54 such as a rectifier bridge and a control chip. Similarly, the second printed circuit board 510 has heat generating elements 54 such as an inductor coil 541 and a control chip. In some embodiments, at least a rectifier circuit is provided on the first printed circuit board 520 for converting the AC power at the input terminal into a DC power supply, so as to be suitable for personal care electrical appliances in particular. In some embodiments, the rectifying device includes at least a diode or a rectifier bridge, and further, at least two current-carrying wires are coupled to the rectifying device.

Advantageously, as shown in FIGS. 3-5, the first printed circuit board 520 and the second printed circuit board 510 are stacked in parallel with each other, and a heat dissipation assembly 2 is provided between the first printed circuit board 520 and/or the second printed circuit board 510 and the housing, and/or between the first printed circuit board 520 and the second printed circuit board 510. In addition, the first printed circuit board 520 and the second printed circuit board 510 are disposed perpendicular to the plugging direction of the prongs 32, wherein the prongs 32 are coupled to the second printed circuit board 510 or the first printed circuit board 520 via the current-carrying wires 31.

Using such a structure, the leakage protection device of the present embodiment integrates additional functional assembly in a limited housing space with an optimized structural layout, ensuring the reliability of the leakage protection device while providing more diversified functions. In addition, by providing a heat dissipation assembly, it facilitates the heat dissipation of the heat generating elements on the first printed circuit board and the second printed circuit board, and the heat dissipation surface may be maximized by optimizing the structure and layout of the heat dissipation assembly to avoid excessively high local temperatures on the housing surface, so that the device is safe and reliable to use in addition to providing diversified functions.

Advantageously, the heat dissipation assembly is disposed adjacent to the heat generating elements on the first printed circuit board and/or the second printed circuit board for dissipating heat for the heat generating element, which also achieves effective heat dissipation while providing a compact structure. Further advantageously, the heat generating elements 54 on the first printed circuit board 520 and the second printed circuit board 510 are disposed to face opposite directions and toward the inner surface of the housing, so that the heat generating elements and the heat dissipation assembly are adjacent to each other to facilitate heat dissipation, and at the same time, the processing and assembly difficulty of the heat dissipation element may be reduced.

In some embodiments, the second printed circuit board 510 may be provided for the leakage protection assembly 51, and the second printed circuit board is located farther away from the input terminal compared to the first printed circuit board 520 of the additional functional assembly 52, that is, the second printed circuit board 510 is disposed farther away from the prong 32. Accordingly, the heat dissipation assembly is at least partially disposed between the first printed circuit board 520 and the inner surface of the lower housing 30, so as to dissipate heat from the heat generating elements of the first printed circuit board 520, so as to avoid adverse impact of the heat generated by the elements for providing the additional load end function, and improve the safety of use. By placing the second printed circuit board 510 farther away from the input terminal than the first printed circuit board 520, it makes it convenient to arrange the button assembly of the leakage protection assembly on the upper surface of the housing. In addition, the leakage protection function relies on the zero-sequence current transformer to detect small differences between the hot and neutral currents (usually in the milliampere level). If the second printed circuit board of the leakage protection assembly 51 is close to the input terminal, it is susceptible to interference from large currents, power supply noise and high-frequency harmonics, resulting in misjudgment or decreased sensitivity. The layout that places the detection circuit away from the input terminal can reduce the impact of electromagnetic interference on the signal amplification circuit, ensure the accuracy of leakage detection, and help prevent false triggering or failure caused by voltage fluctuations, thereby ensuring the reliability and response speed of the leakage protection function under complicated working conditions. In some embodiments, the second printed circuit board 510 can also be located closer to the input terminal compared to the first printed circuit board 520. Accordingly, the heat dissipation assembly is at least partially disposed between the first printed circuit board 520 and the inner surface of the upper housing 10.

FIGS. 3-5 respectively show an assembled and a disassembled views of the core assembly 5 including the leakage protection assembly 51 and the additional functional assembly 52, and illustrates a heat dissipation assembly according to an embodiment of the present invention.

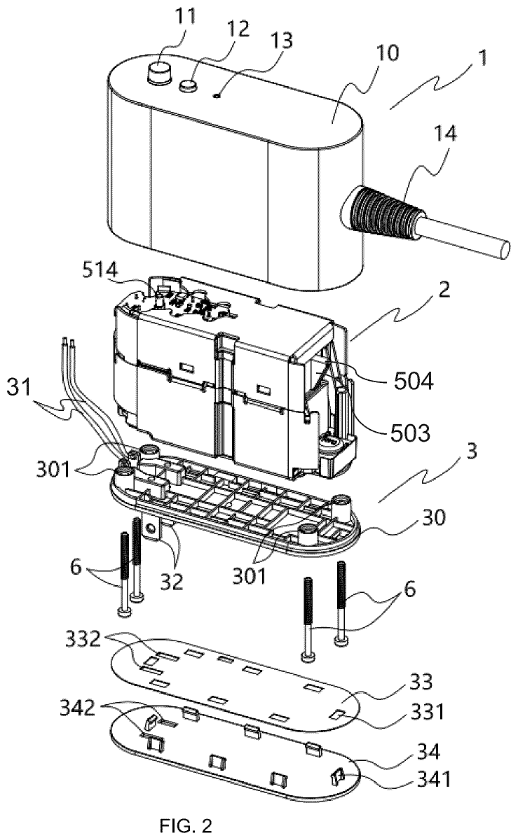

In the illustrated embodiment, the leakage protection device further includes a middle bracket 53, which is disposed between the leakage protection assembly 51 and the additional functional assembly 52. Some electrical components of the leakage protection assembly 51 and the additional functional assembly 52 may be accommodated in the middle bracket 53 or positioned and supported by the middle bracket 53, wherein the first printed circuit board 520 and the second printed circuit board 510 may be electrically connected via the current-carrying wires 55 that pass through the middle bracket 53. Referring to FIG. 2, it can also be seen that the lower housing 30 is provided with screw holes 301 at the edge, and assembly screws 6 can pass through the screw holes 301 and the bracket screw column 531 of the middle bracket 53, and be assembled and fixed with the screw holes (not shown) of the upper housing 10.

According to embodiments of the present disclosure, the heat dissipation assembly includes at least one heat dissipation element, which has a base wall parallel to the first printed circuit board or the second printed circuit board, and at least one pair of side walls extending vertically from the edge of the base wall and parallel to each other. The base wall is disposed at least between the first printed circuit board or the second printed circuit board and the inner surface of the housing, and the at least one pair of side walls cover at least a portion of the core assembly.

In the embodiments shown in FIGS. 2-5, the heat dissipation assembly 2 may include a first heat dissipation element 22 and a second heat dissipation element 21, wherein the first heat dissipation element 22 has a first base wall 223 parallel to the first printed circuit board 520, and at least one pair of first side walls 222 extending vertically from the edge of the first base wall 223 and parallel to each other, the first base wall 223 is disposed between the first printed circuit board 520 and the inner surface of the housing (lower housing 30) to be disposed adjacent to the heat generating elements 54 on the first printed circuit board 520. The at least one pair of first side walls 222 cover at least a portion of the additional functional assembly 52 to form a heat dissipation portion. Similarly, the second heat dissipation element 21 has a second base wall 213 parallel to the second printed circuit board 510, and at least one pair of second side walls 212 extending vertically from the edge of the second base wall 213 and parallel to each other. The second base wall 213 is disposed between the second printed circuit board 510 and the inner surface of the housing (upper housing 10) to be close to the heat generating elements 54 on the second printed circuit board 510. The at least one pair of second side walls 212 cover at least a portion of the leakage protection assembly 51 to form a heat dissipation portion.

In the illustrated embodiment, the first heat dissipation element 22 and the second heat dissipation element 21 may be configured as plate-like members, and the corresponding base wall and the bent and extended side walls are integrally formed by stamping. In addition, in the illustrated embodiment, the first heat dissipation element 22 and the second heat dissipation element 21 are respectively formed into an approximate U-shape. The heat dissipation assembly may also be configured in other appropriate forms depending on different needs. For example, the heat dissipation assembly may have a first base wall parallel to the first printed circuit board or the second printed circuit board, and at least one pair of side walls extending vertically from the edge of the first base wall and parallel to each other, the first base wall being disposed between the first printed circuit board and the inner surface of the housing, and the heat dissipation assembly also has a second base wall parallel to the first base wall and disposed between the second printed circuit board and the inner surface of the housing, where the at least one pair of side walls cover at least a part of the additional functional assembly. In this way, the heat dissipation assembly may be configured to include at least a first heat dissipation element and a second heat dissipation element, wherein the first heat dissipation element includes at least a first base wall, and the second heat dissipation element includes at least a second base wall. For example, the first heat dissipation element and the second heat dissipation element may be respectively configured to be substantially L-shaped, or the first heat dissipation element may be configured to be substantially U-shaped and the second heat dissipation element may be configured to be substantially flat plate-shaped, etc.

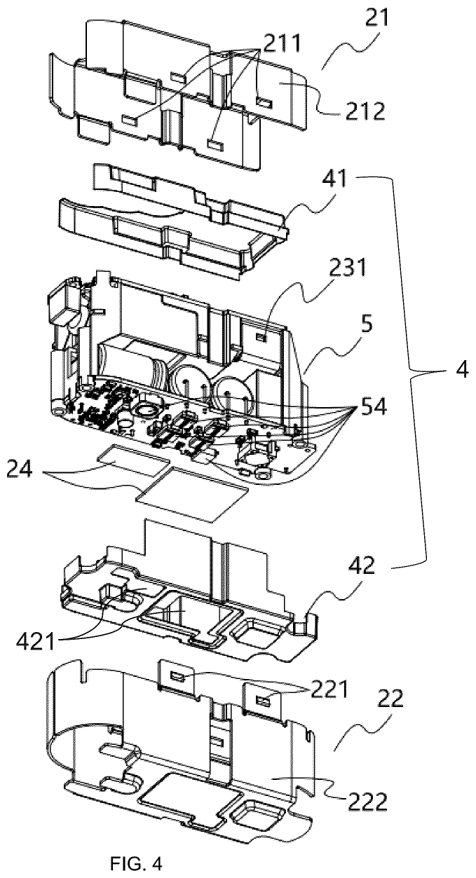

Advantageously, the first heat dissipation element 22 and the second heat dissipation element 21 are connected to each other and cover at least a portion of the core assembly. In some embodiments, the first heat dissipation element 22 and the second heat dissipation element 21 may be fixedly connected by a snap-fit structure provided on the at least one pair of first side walls 222 and the at least one pair of second side walls 212. For example, as shown in FIG. 3 and FIG. 4, a snap hook 221 may be provided on the first side wall 222, and a snap slot 211 may be provided on the second side wall 212, so that the snap-fit attachment of the heat dissipation assembly 2 may be conveniently achieved after the core assembly 5 is assembled. Advantageously, the at least one pair of first side walls 222 of the first heat dissipation element 22 and the at least one pair of second side walls 212 of the second heat dissipation element 21 partially overlap. In this way, the heat dissipation assembly 2 provides sufficient heat dissipation surface in a limited housing space to facilitate heat dissipation of the heat generating elements on the first printed circuit board 520 and the second printed circuit board 510 and prevent local overheating of the housing surface.

In certain embodiments, the heat dissipation element may further include at least one pair of side surrounding walls, which extend at an angle from the edges of the at least one pair of side walls or extend vertically from the edge of the base wall and are connected to or spaced apart from the at least one pair of side walls, where the at least one pair of side surrounding walls extend toward each other to cover at least a portion of the core assembly.

Specifically, in the illustrated embodiment, the first heat dissipation element 22 further includes at least one pair of first side surrounding walls 225, which extend at an angle from the edge of the at least one pair of first side walls 222, and the at least one pair of first side surrounding walls 225 extend toward each other to cover at least a part of the additional functional assembly 52. Optionally, at least one pair of first side surrounding walls 225 are disposed adjacent to each other to substantially completely cover the side of the additional functional assembly 52, such as the side closer to the input terminal, so as to better achieve the heat dissipation effect. The pair of first side surrounding walls closer to the side of the output terminal may be spaced apart from each other to facilitate the wiring of the output terminal. Similarly, the second heat dissipation element 21 may also include at least one pair of second side surrounding walls 214, which extend at an angle from the edge of at least one pair of second side walls 211, and extend toward each other to cover at least part of the leakage protection assembly 51. Similarly, optionally, the at least one pair of second side walls 214 may be disposed adjacent to each other or spaced apart.

In an additional embodiment, the heat dissipation assembly may further include at least one heat conductor, which is disposed corresponding to the positions of the heat generating elements on the first printed circuit board and/or the second printed circuit board, and is in contact with both the heat generating elements and at least one heat dissipation element to form a heat conduction path for transferring heat between the heat generating elements and the heat dissipation element.

As shown in FIG. 3 and FIG. 4, two heat conductors 24 are exemplarily shown for the heat generating elements 54 on the first printed circuit board 520. As mentioned earlier, in some embodiments, at least a rectifier is provided on the first printed circuit board 520; one heat conductor is advantageously provided on the surface of the rectifier. Depending on different needs, the heat conductors 24 may be selected from, for example, mica sheets, ceramic heat conductors, metal heat conductors combined with insulating layers, heat conducting silica gel, heat conducting mud, etc.

In some embodiments, the leakage protection device may further include at least one insulator 4, which is disposed between the heat dissipation assembly 2 and the non-heat generating elements and/or conductive parts of the first printed circuit board 520 and/or the second printed circuit board 510 for isolation and insulation, so as to ensure the insulation strength between the heat dissipation assembly 2 and the first printed circuit board and/or the second printed circuit board. In the embodiments shown in FIGS. 3 and 4, the leakage protection device includes a first insulator 42 disposed between the first heat dissipation element 22 and the non-heat generating elements of the first printed circuit board 520, and a second insulator 41 disposed between the second heat dissipation element 21 and the non-heat generating elements of the second printed circuit board 510.

Advantageously, the contour shapes of the first insulator 42 and the first heat dissipation element 22 are configured to at least partially match each other, and/or the contour shapes of the second insulator 41 and the second heat dissipation element 21 are configured to at least partially match each other, so as to achieve a compact structural design. In the case where heat conductors are provided, at least one insulator may have an opening, and at least one of the heat conductors is in contact with at least one of the heat dissipation elements via the opening. For example, as shown in FIG. 4, the first insulator 42 is provided with an opening 421 corresponding to the heat conductor 24. Advantageously, the shapes of the opening 421 and the heat conductor 24 match each other.

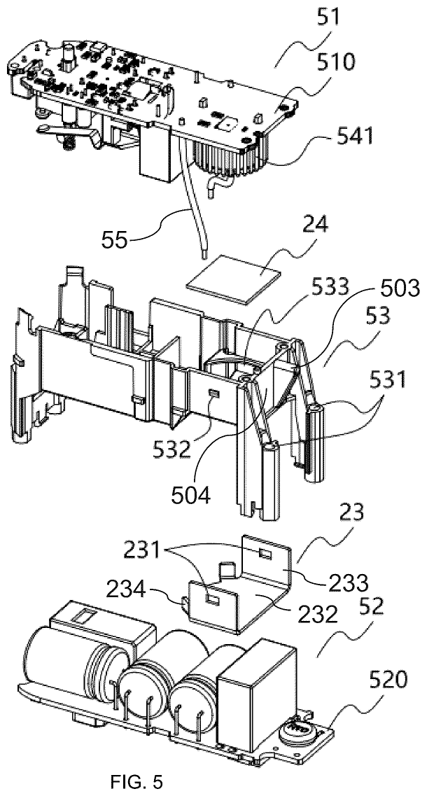

Advantageously, the heat dissipation assembly may include a middle-layer heat dissipation element, which is disposed in the middle bracket and adjacent to the heat generating elements of the first printed circuit board and/or the second printed circuit board, to achieve enhanced heat dissipation effect for individual heat generating elements. As shown in FIG. 5, for example, a middle-layer heat dissipation element 23 may be separately provided for the inductor 541 of the leakage protection assembly 51. Specifically, the middle-layer heat dissipation element 23 has a middle-layer base wall 232 parallel to the second printed circuit board 510, and at least one pair of middle-layer side walls 233 extending vertically from the edge of the middle-layer base wall 232 and parallel to each other. The middle-layer base wall 232 is disposed between the second printed circuit board 510 and the middle bracket 53, and at least one pair of the middle-layer side walls 233 cover at least part of the heat generating elements (inductor 541) of the second printed circuit board 510.

Optionally, the middle-layer heat dissipation element 23 and the middle bracket 53 are fixedly connected together by a snap-fit structure and/or fasteners. For example, a snap slot 231 may be provided on the middle-layer heat dissipation element 23, which may be snap-fitted with a snap hook 532 on the middle bracket 53 to be fixed on the middle bracket 53. In the illustrated embodiment, a bracket through hole 533 may be provided at a position corresponding to the inductor 541 on the middle bracket 53, and a heat conductor 24 may be optionally provided in the bracket through hole 533. The heat conductor 24 is in contact with the inductor 541 and the middle-layer heat dissipation element 23 to form a heat-conducting path, so as to transfer the heat of the inductor 541 to the middle-layer heat dissipation element 23. In addition, the heat dissipation portion formed by the middle-layer side wall 233 of the middle-layer heat dissipation element 23 may be in close contact with the heat dissipation portions of the first heat dissipation element 22 and the second heat dissipation element 21 to form an effective heat dissipation path for the entire core assembly 5.

In some embodiments, the middle-layer heat dissipation element may also include at least one pair of middle-layer side surrounding walls, which extend at an angle from the edge of the at least one pair of middle-layer side walls or extend vertically from the edge of the middle-layer base wall, and are connected to or spaced apart from the at least one pair of middle-layer side walls. The at least one pair of middle-layer side surrounding walls extend toward each other to cover at least part of the heat generating elements of the first printed circuit board or the second printed circuit board. As shown in FIG. 5, the middle-layer heat dissipation element 23 includes a pair of middle-layer side surrounding walls 234 extending vertically from the edge of the middle-layer base wall 232 and spaced apart from the at least one pair of middle-layer side walls 233, configured to cover at least part of the inductor 541, thereby achieving a better heat dissipation effect. Optionally, the at least one pair of middle-layer side surrounding walls may be adjacent to each other or spaced apart; the pair of middle-layer side surrounding walls 234 shown in the figure are spaced apart from each other as an example.

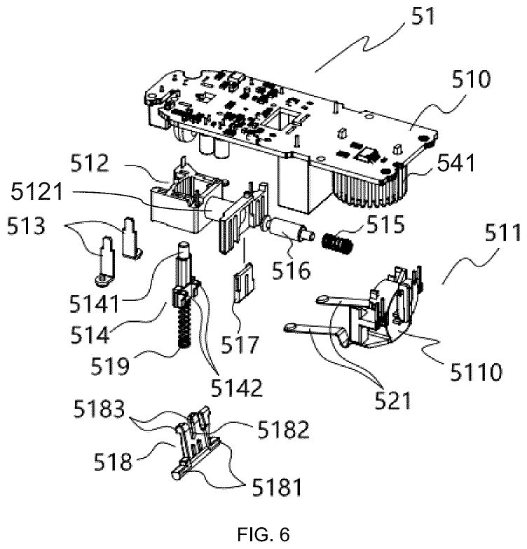

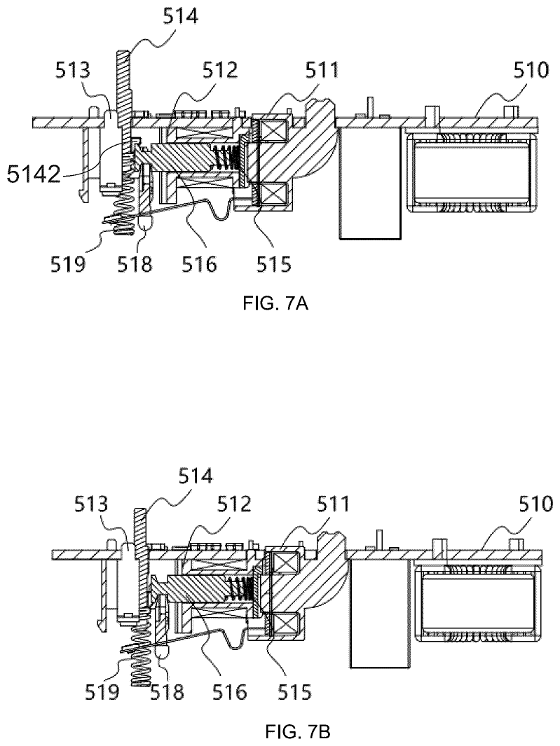

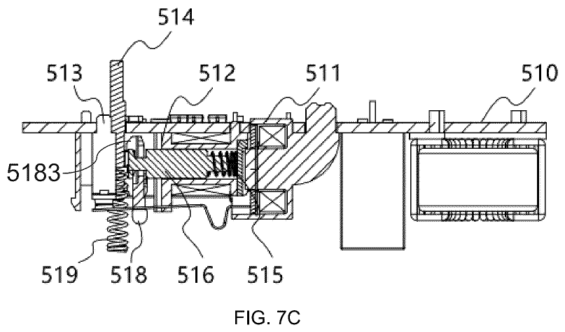

Referring to FIG. 6 to FIG. 7C, in some embodiments, the leakage protection assembly 51 includes at least a detection assembly and a disconnection assembly, where the detection assembly detects the leakage current signal at the output terminal, and the disconnection assembly disconnects the electrical connection between the input and output terminals in response to the detected leakage current signal. It should be understood that the disconnection assembly may be any structure capable of disconnecting the electrical connection between the input terminal and the output terminal, and may also be referred to as a switch assembly, for example, including, without limiting, a pair of contact arms with contact terminals that accomplishes electrical connection and disconnection.

In the illustrated embodiment, the detection assembly 511 may include a detection magnetic ring 5110, which has an inner hole and is coupled to the second printed circuit board 510, and is used to detect the leakage current signal of the current-carrying wires passing through the inner hole and transmit it to the second printed circuit board 510. The disconnection assembly may include an input stationary contact assembly 513 coupled to the input terminal, and an output moving contact assembly 521 passing through the inner hole of the detection magnetic ring 5110 and coupled to the output terminal. The input stationary contact assembly 513 has stationary electric contact terminals and is coupled to the prong 32 through the current-carrying wires 31, and the output moving contact assembly 521 has a moving electric contact terminal and is coupled to the output power cord assembly 14 after passing through the inner hole of the detection assembly 511. The disconnection assembly disconnects the electrical connection between the input stationary contact assembly 513 and the output moving contact assembly 521 in response to the leakage current signal. The leakage protection assembly 51 also includes an operating member mechanically linked to the disconnection assembly. The operating member includes a reset member 514 and a tripping member 518 to switch the input stationary contact assembly 513 and the output moving contact assembly 521 between a closed state and an open state, that is, the output moving contact assembly 521 may be driven by the operating member to close and connect with the input stationary contact assembly 513, or to separate and disconnect from the input stationary contact assembly 513 due to its own elastic deformation rebound force.

More specifically, referring to FIG. 6, the reset member 514 is in the form of a reset rod, one end of which is a reset plate head end 5141, which may cooperate with the reset button 11 that protrudes from the upper housing 10 (FIG. 2). The other end of the reset rod abuts against one end of the reset spring 519, and the other end of the reset spring 519 abuts against the middle bracket 53, which provides an upward rebound force to the reset member 514. In some embodiments, the operating member further includes a test member, which is coupled to the second printed circuit board 510 and configured to generate a simulated leakage signal. As shown in FIG. 2, the test member includes a test button 12. In some embodiments, the leakage protection device may also include a status indicator 13, which is formed of a light-transmitting material and is disposed between the second printed circuit board 510 and the housing (upper housing 10) so that the working state of the leakage protection device may be visually observed from the outside of the housing.

Referring back to FIG. 6, in the illustrated embodiment, the tripping member 518 and the tripping coil assembly 512 cooperate with each other. The tripping coil assembly 512 includes a hollow winding column 5121, the outer side of which is wound with a coil winding electrically coupled to the second printed circuit board 510, and a tripping core 516 is disposed in the inner hole of the hollow winding column 5121. The head end of the tripping core 516 has a neck engaged with the tripping member 518, and the tail of the tripping core 516 abuts against one end of the core spring 515. The other end of the core spring 515 abuts against the side of the spring baffle 517, and the spring baffle 517 is partially inserted into and fixed to the end of the inner hole of the hollow winding column 5121. The tripping member 518 has a tripping notch 5182, a tripping buckle 5183, and a tripping lifting arm 5181, where the tripping notch 5182 is engaged with the head end of the tripping core 516 via the neck and can move with the movement of the tripping core 516. The reset member 514 correspondingly has a reset buckle 5142 on a side of the reset rod to engage with or separate from the tripping buckle 5183. The tripping lifting arm 5181 is configured to contact the output moving contact assembly 521 to switch the input stationary contact assembly 513 and the output moving contact assembly 521 between the closed state and the open state. It should be understood that the structures of the reset member 514 and the tripping member 518 shown in the figure are only examples, and depending on different needs, the above structures may be changed accordingly to achieve similar reset and tripping functions.

Referring to FIGS. 7A-7C, in the initial state, as shown in FIG. 7A, the core spring 515 is in a compressed state and applies a rebound force to the tripping core 516; as the tripping core 516 is subjected to the elastic force of the core spring 515, the tripping buckle 5183 applies a maintaining force to the tripping member 518 in the direction of the reset member 514, to urge it to engage with the reset buckle 5142 of the reset member 514. When the reset button 11 is pressed, the mechanically linked reset member 514 moves downward and compresses the reset spring 519 until the tripping buckle 5183 of the tripping member 518 engages with the reset buckle 5142 of the reset member 514, as shown in FIG. 7B. At this time, if the reset button 11 is released, the reset member 514 will drive the tripping member 518 and the output moving contact assembly 521 to move upward under the action of the rebound force of the reset spring 519, forcing the output moving contact assembly 521 to undergo elastic deformation until the output moving contact assembly 521 is connected and closed with the input stationary contact assembly 513, as shown in FIG. 7C.

When the detection assembly 511 detects the leakage current signal, the tripping coil assembly 512 is energized in response to the control of the second printed circuit board 510 and generates a magnetic field to drive the tripping core 516 to compress the core spring 515 and pull the tripping member 518, thereby separating the tripping buckle 5183 of the tripping member 518 and the reset buckle 5142 of the reset member 514 (i.e. tripping). At a result, the tripping lifting arm 5181 of the tripping member 518 moves downward to its initial position under the action of the deformation rebound force of the output moving contact assembly 521, and the output moving contact assembly 521 is separated and disconnected from the input stationary contact assembly 513, as shown in FIG. 7A, thereby achieving leakage protection.

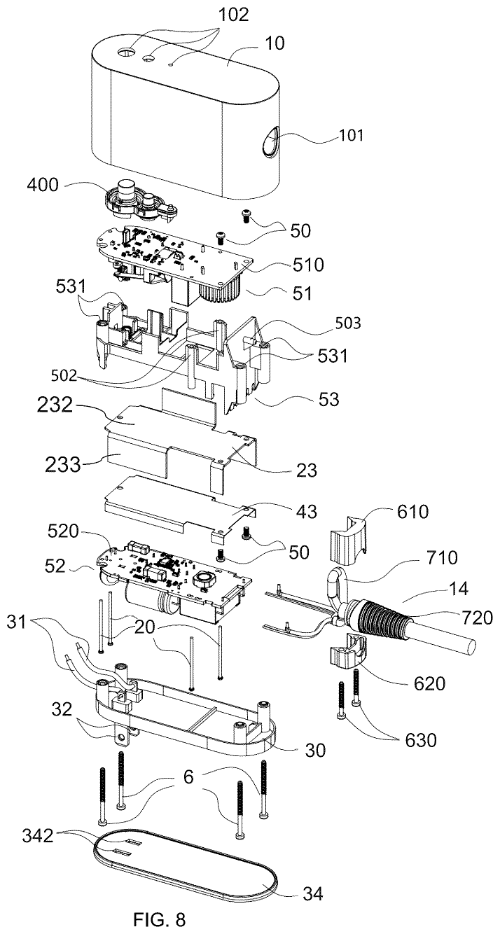

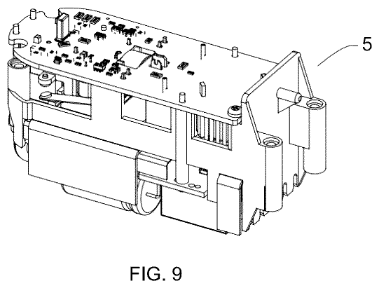

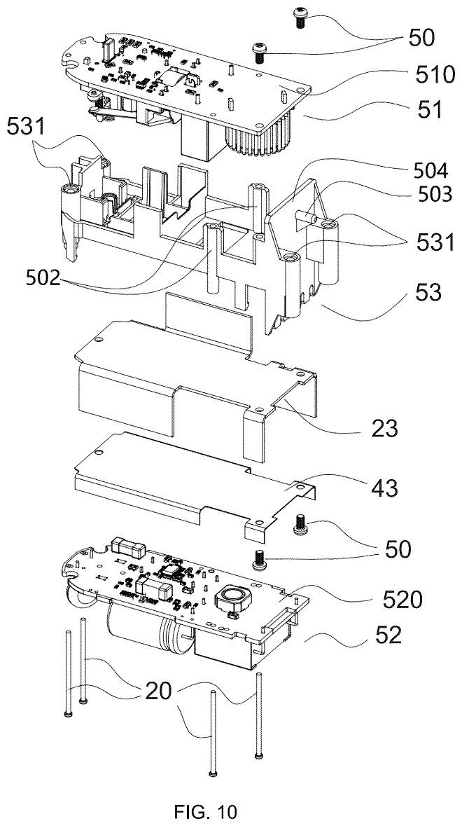

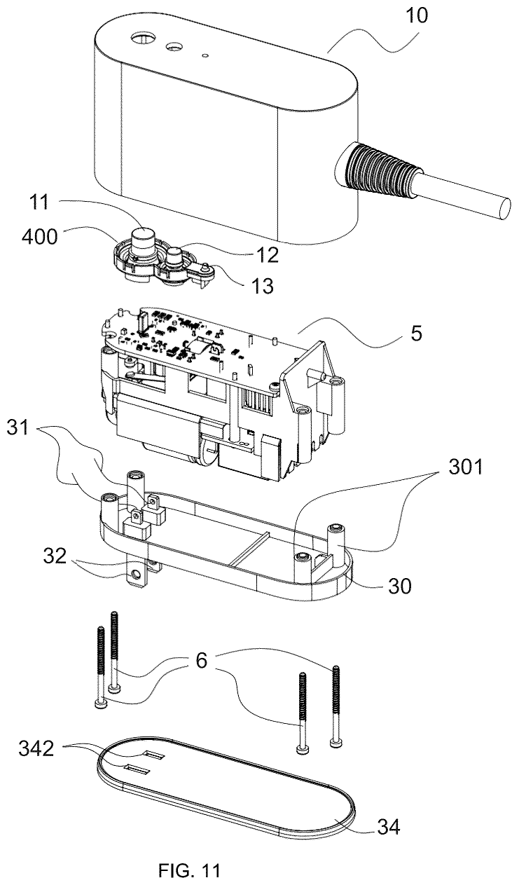

FIGS. 8-13B show a leakage protection device according to another embodiment of the present disclosure. Here, components similar to those in the above embodiment are shown with the same reference numerals, and for the sake of brevity, descriptions of similar components are not repeated.

In this embodiment, the heat generating elements on the first printed circuit board 520 and the second printed circuit board 510 are disposed in the same direction, and the heat dissipation element may be a middle-layer heat dissipation element 23 disposed on the middle bracket 53, and for example, disposed adjacent to the first printed circuit board 520. The middle-layer heat dissipation element 23 may be a substantially plate-shaped member, and has a middle-layer base wall 232 parallel to the first printed circuit board 520 and a pair of middle-layer side walls 233 vertically bent from the edges of the middle-layer base wall 232 in opposite directions and extending parallel to each other to form a heat dissipation portion, which is used to dissipate heat from the heat generating elements on the first printed circuit board 520 and the second printed circuit board 510, respectively.

In this embodiment, the middle-layer heat dissipation element 23 and the middle bracket 53 are fixedly connected, for example, by fasteners and may be provided with a middle-layer insulator 43. The middle-layer insulator 43 may be disposed between the first printed circuit board 520 and the middle-layer heat dissipation element 23, and may be fixed to the middle bracket 53 together with the middle-layer heat dissipation element 23 by fixing screws 50. In addition, the middle bracket 53 may have a conductive column through hole 502, and the conductive column 20 passes through the conductive column through hole 502, and its two ends are respectively connected to the first printed circuit board 520 and the second printed circuit board 510, so as to achieve the electrical connection between the two circuit boards.

According to different needs, the reset button 11 and the test button 12 may be assembled and combined with the status indicator 13 to form a button assembly 400, as shown in FIG. 8. Accordingly, the upper housing 10 is provided with a guide hole 102 for the reset button 11 and the test button 12 to protrude, so as to facilitate the operation of the reset member and the test member. In the case of the status indicator 13 is provided, the guide hole 102 is also used to expose the status indicator 13.

According to embodiments of the present invention, the leakage protection device may further include a wire crimping assembly 600, as shown in the embodiment of FIG. 8, where the wire crimping assembly 600 is configured to fix the output power cord to the housing, and is configured to move only along the plugging direction of the prong 32, so as to facilitate the assembly and fixing of the power cord. More specifically, the wire crimping assembly 600 is disposed in the housing and adjacent to the output terminal through hole 101 of the housing. The output power cord assembly 14 of the leakage protection device may also be provided with a power cord bending buffer device 720, and the power cord bending buffer device 720 is provided with a snap-fitting convex edge 721, and the snap-fitting convex edge 721 can pass through the output terminal through hole 101 of the housing and fixedly engage with the wire crimping assembly 600.

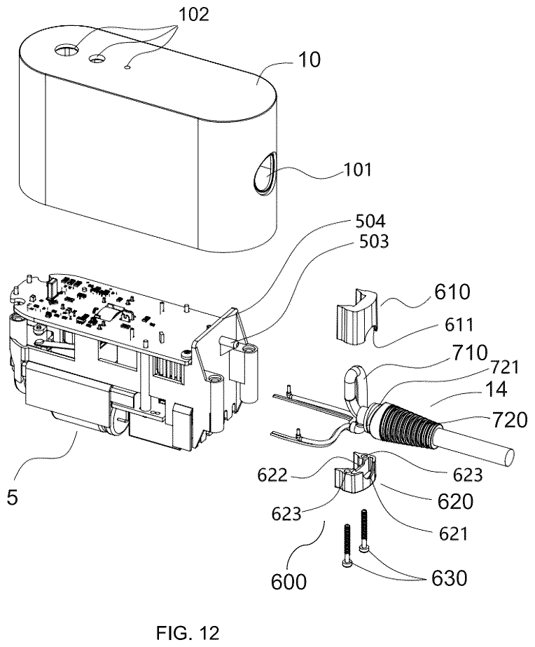

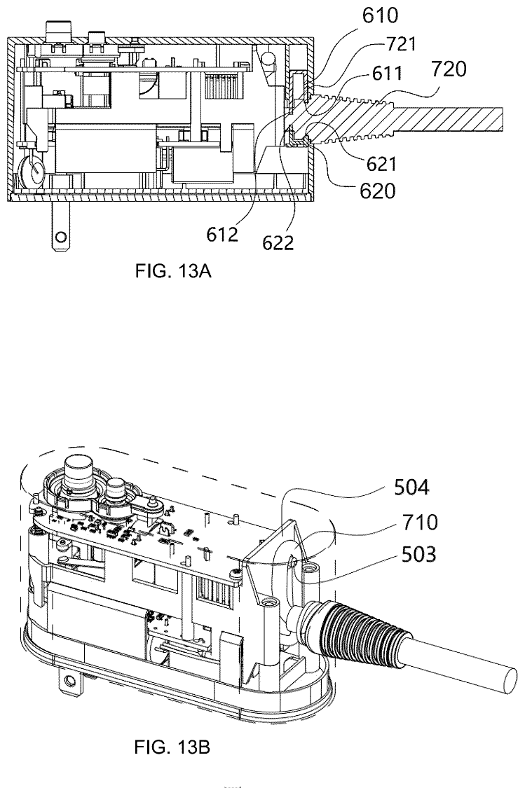

In some embodiments, the wire crimping assembly 600 may include a first wire pressing block 610 and a second wire pressing block 620 disposed opposite to each other along the plugging direction of the prongs, where the first wire pressing block 610 is provided with first notches (two first notches 611 and 612 are exemplarily shown in FIG. 13A), and the second wire pressing block 620 is provided with second notches (two second notches 621 and 622 are exemplarily shown in the figure), so that the snap-fitting convex edge 721 is fixed between the two first notches 611 and 612 and between the two second notches 621 and 622. The first wire pressing block 610 and the second wire pressing block 620 may be affixed to each other by wire pressing screws 630, and screw hole 623 on the second crimping block 620 are exemplarily shown in FIG. 12.

Advantageously, the first notches and/or the second notches are provided with inclined surfaces. For example, as shown in the figure, the corresponding first notch 611 and second notch 621 are respectively provided with inclined surfaces. When the two wire pressing blocks are fastened by the wire pressing screw 630, the inclined surface may be engaged with the snap-fitting convex edge 721 of the power cord bending buffer device 720, so that the power cord bending buffer device 720 abuts the edge of the output terminal through hole 101 of the upper housing 10, further realizing the stable engagement of the wire crimping assembly with the power cord. In addition, the combination of the two pairs of notches may be engaged with the outer skin of the output power cord and compress and deform the outer skin of the power cord, so that it is fastened to the wire crimping assembly and the housing.

In some embodiments, a wire management block 503 may also be provided on the middle bracket 53 for bending the power cord. Referring to FIGS. 12-13B, the wire management block 503 is disposed adjacent to the output power cord assembly 14. A wire baffle 504 is optionally provided, and the wire management block 503 is formed on the wire baffle 504. In this way, the wire baffle 504 separates the internal space of the housing to form a relatively independent wire storage space, which is conducive to the positioning and protection of the power cord. When the output power cord assembly 14 is assembled and the core assembly 5 is installed in the upper housing 10, the output power cord inside the housing may be arranged into a U-shaped feature 710 by the wire management block 503, and pushed together with the core assembly 5 into the housing and fixed in the wire storage space.

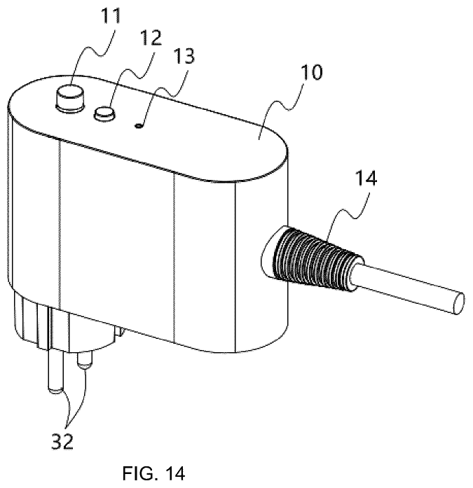

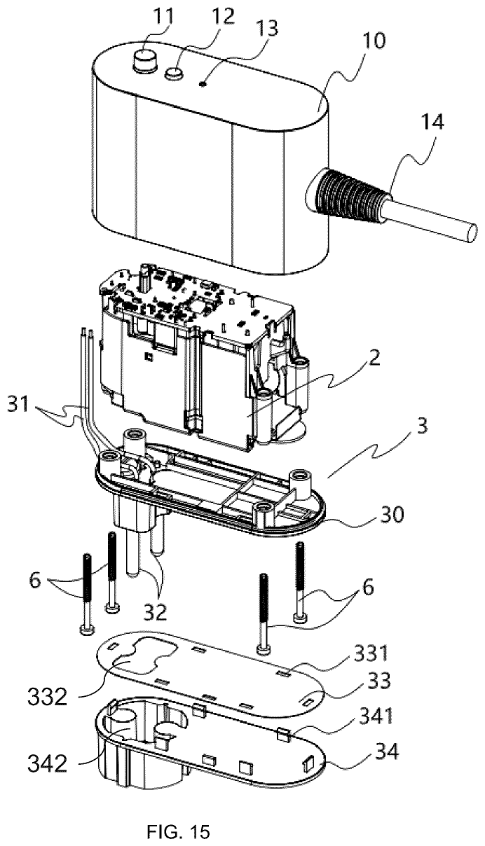

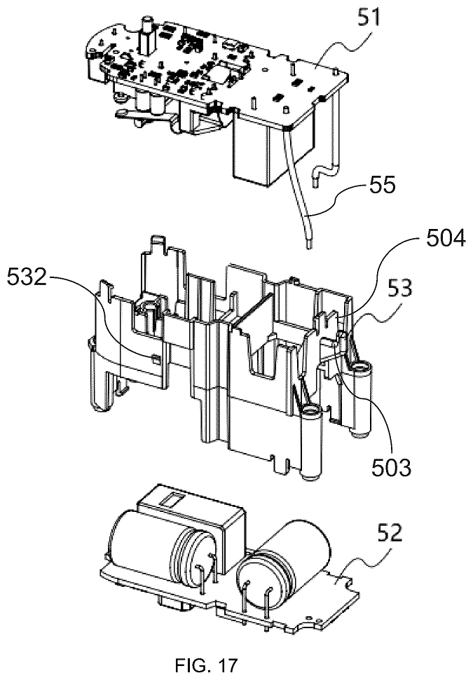

FIGS. 14-17 show a leakage protection device according to another embodiment of the present disclosure. Similarly, components similar to those in the above embodiments are shown with the same reference numerals, and for the sake of brevity, descriptions of similar components are not repeated.

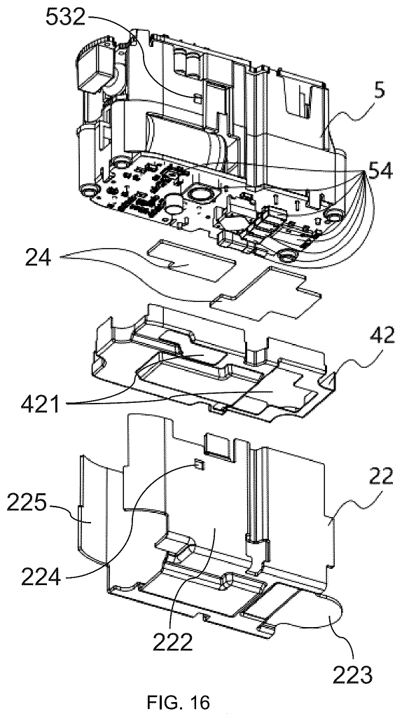

In this embodiment, the prongs 32 at the input terminal have a different configuration from that of the above embodiments, but they are still fixed to the lower housing 30. Due to the modified configuration of the prongs 32, the corresponding through holes 342 for the prongs 32 to extend out of the lower housing cover plate 34 and the corresponding through holes 332 for the prongs 32 to extend out of the adhesive sheet 33 have correspondingly modified configurations. Some differences between this embodiment and the previous embodiments, especially the embodiment shown in FIGS. 2-5, are that the heat dissipation assembly 2 in this embodiment includes only one heat dissipation element, that is, the first heat dissipation element 22 disposed between the first printed circuit board 520 and the inner surface of the housing (lower housing 30), and that the first side wall 222 of the first heat dissipation element 22 extends to cover most of the entire core assembly 5, for example, it extends to a position roughly at the same height of the second printed circuit board 510, so that the core assembly as a whole can still achieve effective heat dissipation. Accordingly, in this embodiment, the first heat dissipation element 22 may be directly affixed to the middle bracket 53. For example, as shown in FIG. 16, the middle bracket 53 may be provided with a snap hook 532, and the first heat dissipation element 22 may be correspondingly provided with a snap slot 224, so that the two are fixedly connected by snapping.

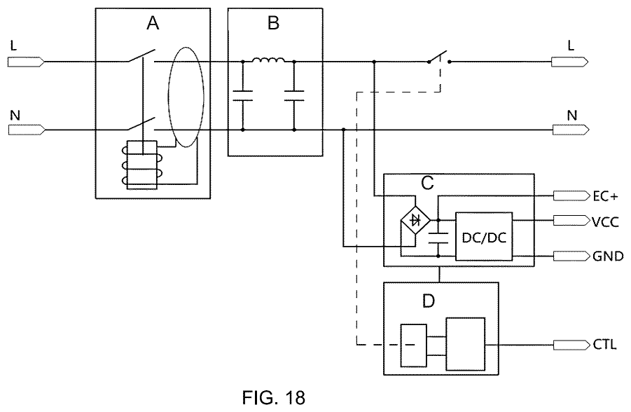

The working principles of the leakage protection device according to embodiments of the present invention are summarized below with reference to FIG. 18.

In FIG. 18, the leakage protection assembly and additional functional assembly are schematically illustrated in a modular manner by regions in the drawing, including a leakage protection module A, an electromagnetic compatibility module B, a power conversion module C and a switch control module D. Under normal working conditions, when a leakage current is present at the output terminal (hot wire L, neutral wire N), the tripping coil assembly of the leakage protection module A receives a large current to generate a magnetic field, which drives the tripping part to move and disconnect the electrical connection between the input and output terminals to achieve leakage protection.

For the additional functions, the electromagnetic compatibility module B functions to reduce the electromagnetic interference (EMI) in the circuit and improve the electromagnetic compatibility (EMC) of the circuit using elements such as capacitors and inductors. The power conversion module C functions to convert the external AC or DC current (such as EC+) at the input terminal into a DC output (such as VCC) that has been voltage regulated or converted using elements such as rectifiers and voltage regulators, thereby improving the stability of the DC output voltage. As a result, while ensuring the safety of the circuit, the EMC interference signal is reduced, thereby reducing the interference to the transformer circuit, ensuring that the leakage protection device is less disturbed during operation, making the output DC voltage value more accurate and the error smaller, thereby achieving a better leakage protection effect. The switch control module D functions to control the switch state of the circuit, allowing the circuit to be controlled by the received external control signal (such as CTL).

Through the above-described layout optimization design, the leakage protection device according to embodiments of the present invention has additional functions such as power conversion, electromagnetic compatibility, and switch control in addition to the leakage protection function and within a limited housing space, which increases integration of electrical appliances. At the same time, by providing a heat dissipation assembly and optimizing the structure and layout of the heat dissipation assembly according to different needs, it achieves effective heat dissipation for the heat generating elements, providing users with a richer, safer and more reliable leakage protection device integration solution.

It should be understood that the embodiments shown in the drawings only illustrate the preferred shapes, sizes and spatial arrangements of the various components of the leakage current protection device. These illustrations do not limit the scope of the invention; other shapes, sizes and spatial arrangements may be used without departing from the spirit of the invention.

It will be apparent to those skilled in the art that various modification and variations may be made in the embodiments of the present invention without departing from the spirit or scope of the invention. Thus, it is intended that the present invention cover modifications and variations that come within the scope of the appended claims and their equivalents.

1. A leakage protection device with additional functions, comprising:
a housing;
an input terminal attached to a lower surface of the housing, for coupling to a power supply;
an output terminal for coupling to an electrical load; and
a core assembly disposed in the housing, including:
a first printed circuit board and a second printed circuit board, wherein the first printed circuit board and the second printed circuit board are stacked parallel to each other, and component surfaces of the first printed circuit board and the second printed circuit board are parallel to the lower surface of the housing;
a leakage protection assembly, including at least a trip coil assembly and a detection magnetic ring, configured to detect a leakage current signal at the output terminal;
an additional functional assembly, coupled to the leakage protection assembly and including at least one of the first printed circuit board and the second printed circuit board, configured to perform at least one load end function; and
a heat dissipation assembly disposed between the first printed circuit board and/or the second printed circuit board and the housing and/or between the first printed circuit board and the second printed circuit board.

2. The leakage protection device of claim 1, wherein the heat dissipation assembly is disposed adjacent to heat generating elements on the first printed circuit board and/or the second printed circuit board, and configured to dissipate heat for the heat generating elements.

3. The leakage protection device of claim 2, wherein the heat generating elements on the first printed circuit board and the heat generating elements on the second printed circuit board are disposed to face opposite directions and toward inner surfaces of the housing.

4. The leakage protection device of claim 1, wherein the heat dissipation assembly includes at least one heat dissipation element, which includes a base wall parallel to the first printed circuit board or the second printed circuit board and at least one pair of side walls extending vertically from edges of the base wall and parallel to each other, wherein the base wall is disposed at least partially between the first printed circuit board or the second printed circuit board and the inner surface of the housing, and the at least one pair of side walls cover at least a portion of the core assembly.

5. The leakage protection device of claim 4, wherein the heat dissipation element further includes at least one pair of side surrounding walls, which extend at an angle from edges of the at least one pair of side walls or extend vertically from edges of the base wall and are connected to or spaced apart from the at least one pair of side walls, and the at least one pair of side surrounding walls extend toward each other to cover at least a portion of the core assembly.

6. The leakage protection device of claim 5, wherein the at least one pair of side surrounding walls are adjacent to each other or spaced apart from each other.

7. The leakage protection device of claim 4, wherein the heat dissipation assembly further includes at least one heat conductor, disposed corresponding to positions of the heat generating elements on the first printed circuit board and/or the second printed circuit board, and in contact with both the heat generating elements and the at least one heat dissipation element to form a heat conduction path.

8. The leakage protection device of claim 7, further comprising at least one insulator, disposed between the at least one heat dissipation element and non-heat generating elements of the first printed circuit board and/or the second printed circuit board for isolation and insulation, wherein respective contour shapes of the at least one insulator and the at least one heat dissipation element at least partially match each other.

9. The leakage protection device of claim 8, wherein the at least one insulator has an opening, and the at least one heat conductor is in contact with the at least one heat dissipating element via the opening, wherein shapes of the opening and the heat conductor match each other.

10. The leakage protection device of claim 1, wherein the heat dissipation assembly includes:
a first base wall parallel to the first printed circuit board or the second printed circuit board, and at least one pair of side walls extending vertically from edges of the first base wall and parallel to each other, wherein the first base wall is disposed between the first printed circuit board and the inner surface of the housing; and
a second base wall parallel to the first base wall, disposed between the second printed circuit board and the inner surface of the housing,
wherein the at least one pair of side walls cover at least a portion of the additional functional assembly.

11. The leakage protection device of claim 10, wherein the heat dissipation assembly includes at least a first heat dissipation element and a second heat dissipation element, wherein the first heat dissipation element includes at least the first base wall, and the second heat dissipation element includes at least the second base wall.

12. The leakage protection device of claim 11, wherein the first heat dissipation element includes at least one pair of first side walls extending vertically from edges of the first base wall and parallel to each other, and the second heat dissipation element includes at least one pair of second side walls extending vertically from edges of the second base wall and parallel to each other.

13. The leakage protection device of claim 12, wherein the first heat dissipation element and the second heat dissipation element are connected to each other and cover at least a portion of the core assembly.

14. The leakage protection device of claim 13, wherein the first heat dissipation element and the second heat dissipation element are fixedly connected to each other by a snap-fit structure on the at least one pair of first side walls and the at least one pair of second side walls.

15. The leakage protection device of claim 12, wherein the at least one pair of first side walls of the first heat dissipation member and the at least one pair of second side walls of the second heat dissipation member partially overlap.

16. The leakage protection device of claim 12,
wherein the first heat dissipation element further includes at least one pair of first side surrounding walls, which extend at an angle from edges of the at least one pair of first side walls or extend vertically from edges of the first base wall and are connected to or spaced apart from the at least one pair of first side walls, wherein the at least one pair of first side surrounding walls extend toward each other to cover at least a portion of the additional functional assembly, and wherein the at least one pair of first side surrounding walls are adjacent to or spaced apart from each other, and/or
where the second heat dissipation element further includes at least one pair of second side surrounding walls, which extend at an angle from edges of the at least one pair of second side walls or extend vertically from edges of the second base wall and are connected to or spaced apart from the at least one pair of second side walls, wherein the at least one pair of second side surrounding walls extend toward each other to cover at least a portion of the leakage protection assembly, and wherein the at least one pair of second side surrounding walls are adjacent to or spaced apart from each other.

17. The leakage protection device of claim 11, further comprising a first insulator disposed between the first heat dissipation element and non-heat generating elements of the first printed circuit board, and a second insulator disposed between the second heat dissipation element and non-heat generating elements of the second printed circuit board,
wherein contour shapes of the first insulator and the first heat dissipation element at least partially match each other, and/or contour shapes of the second insulator and the second heat dissipation element at least partially match each other.

18. The leakage protection device of claim 1, further comprising a middle bracket disposed between the leakage protection assembly and the additional functional assembly, wherein the heat dissipation assembly is affixed to the middle bracket.

19. The leakage protection device of claim 18, wherein the heat dissipation assembly and the middle bracket are fixedly connected to each other by a snap-fit structure and/or fasteners.

20. The leakage protection device of claim 18, wherein the heat dissipation assembly includes a middle-layer heat dissipation element disposed in the middle bracket and adjacent to the heat generating elements of the first printed circuit board and/or the second printed circuit board.

21. The leakage protection device of claim 20, wherein the middle-layer heat dissipation element has a middle-layer base wall parallel to the first printed circuit board or the second printed circuit board, and at least one pair of middle-layer side walls extending vertically from edges of the middle-layer base wall and parallel to each other, wherein the middle-layer base wall is disposed between the first printed circuit board or the second printed circuit board and the middle bracket, and the at least one pair of middle-layer side walls cover at least a portion of the heat generating elements of the first printed circuit board and/or the second printed circuit board.

22. The leakage protection device of claim 21, wherein the middle-layer heat dissipation element further includes at least one pair of middle-layer side surrounding walls, which extend at an angle from edges of the at least one pair of middle-layer side walls or extend vertically from edges of the middle-layer base wall and are connected to or spaced apart from the at least one pair of middle-layer side walls, wherein the at least one pair of middle-layer side surrounding walls extend toward each other to cover at least a portion of the heat generating elements of the first printed circuit board or the second printed circuit board, and wherein the at least one pair of middle-layer side surrounding walls are adjacent to each other or spaced apart.

23. The leakage protection device of claim 20, further comprising a heat conductor disposed between the middle-layer heat dissipation element and the heat generating elements of the first printed circuit board and/or the second printed circuit board, wherein the heat conductor is in contact with both the heat generating elements and the middle-layer heat dissipation element to form a heat conduction path.

24. The leakage protection device of claim 18, wherein the middle bracket further includes a wire baffle and a wire management block formed on the wire baffle for bending the output power cord.

25. The leakage protection device of claim 1, wherein the first printed circuit board and the second printed circuit board are electrically connected by current-carrying wires or a conductive column.

26. The leakage protection device of claim 1, wherein the input terminal includes at least two prongs extending out of the housing, wherein the first printed circuit board and the second printed circuit board are disposed perpendicular to a plugging direction of the prongs, wherein the prongs are coupled to the first printed circuit board or the second printed circuit board by current-carrying wires.

27. The leakage protection device of claim 26, wherein the housing at least includes an upper housing and a lower housing, wherein the upper housing has an output terminal through hole for accommodating an output power cord, and wherein the prongs are fixed to the lower housing; and either:
the first printed circuit board is located farther away from the input terminal compared to the second printed circuit board, and the heat dissipation assembly is at least partially disposed between the first printed circuit board and the inner surface of the upper housing; or
the first printed circuit board is located closer to the input terminal compared to the second printed circuit board, and the heat dissipation assembly is at least partially disposed between the first printed circuit board and the inner surface of the lower housing.

28. The leakage protection device of claim 27, wherein the housing further includes a lower housing cover plate covering the lower housing and fixedly connected to the lower housing by a snap-fit structure and/or fasteners and/or adhesives, the lower housing cover plate having through holes for the prongs to extend out.

29. The leakage protection device of claim 28, wherein the lower housing cover plate is fixedly connected to the lower housing by an adhesive sheet, wherein the adhesive sheet has through holes for the prongs to extend out and snap slots, and the lower housing cover plate has corresponding snap hooks.
